(19) United States
(12) Patent Application Publication
(10) Pub. No.: US 2026/0334205 A1
(43) Pub. Date: Oct. 22, 2026

(54) SEMICONDUCTOR STRUCTURE HAVING FLEXIBLE TYPES OF CELL REGIONS

(71) Applicant: TAIWAN SEMICONDUCTOR MANUFACTURING COMPANY LTD., HSINCHU (TW)

(72) Inventors: JUN-YU LIN, CHIAYI COUNTY (TW); SHIH-WEI PENG, HSINCHU CITY (TW); HUI-ZHONG ZHUANG, KAOHSIUNG CITY (TW); JIANN-TYNG TZENG, HSINCHU (TW)

(21) Appl. No.: 19/182,685

(22) Filed: Apr. 18, 2025

(51) Int. Cl. H10W 20/41; H10W 20/43

(52) U.S. Cl. CPC H10W 20/427; H10W 20/43; H10W 20/435

(57) ABSTRACT

A semiconductor structure comprises a first conductive line, a second conductive line, a third conductive line, a first region, and a second region. The first region comprises a first isolation structure and a second isolation structure extending in the first direction, and a first gate structure and a second gate structure extending in a second direction. The second cell comprises the second isolation structure, a third isolation structure extending in the first direction, the first gate structure, and the second gate structure, wherein the first gate structure intersects with the second conductive line and the third conductive line from the top view. The padding region adjacent to the first region and the second region and disposed between the first gate structure and the third gate structure from the top view.

### TECHNICAL FIELD

The present disclosure relates in general to semiconductor structure. Specifically, the present disclosure relates to a semiconductor structure having different flexible types of cell regions.

### BACKGROUND

One problem faced in currently-available semiconductor process development is that different types of cells may not be able to abut each other freely. Transitioning from one cell type to another requires padding or sacrifice spaces, which results in wasted chip area. Therefore, an improved cell arrangement is called for to minimize such wasted or sacrifice space.

### BRIEF DESCRIPTION OF THE DRAWINGS

Aspects of the embodiments of the present disclosure are best understood from the following detailed description when read with the accompanying figures. It should be noted that, in accordance with the standard practice in the industry, various structures are not drawn to scale. In fact, the dimensions of the various structures may be arbitrarily increased or reduced for clarity of discussion.

FIG. 1A is a top view of a semiconductor structure in accordance with some embodiments of the present disclosure.

FIG. 1B is a top view of a semiconductor structure in accordance with some embodiments of the present disclosure.

FIG. 2A is a top view of a semiconductor structure in accordance with some embodiments of the present disclosure.

FIG. 2B is a top view of a semiconductor structure in accordance with some embodiments of the present disclosure.

FIG. 3 is a top view of a semiconductor structure in accordance with some embodiments of the present disclosure.

FIG. 4 is a top view of a semiconductor structure in accordance with some embodiments of the present disclosure.

FIGS. 5A and 5B are tables showing the padding distance between different cell structures in accordance with some embodiments of the present disclosure.

FIG. 6 is a flowchart of an embodiment of a method of manufacturing a semiconductor device in accordance with some embodiments of the present disclosure.

FIG. 7 is a block diagram of an integrated circuit (IC) manufacturing system.

### DETAILED DESCRIPTION

The following disclosure provides multiple embodiments, or examples, for implementing different features of the provided subject matter. Specific examples of elements and arrangements are described to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90° (degree) or at other orientations) and the spatially relative descriptors used herein may likewise be interpreted accordingly.

As used herein, although terms such as "first," "second" and "third" describe various elements, components, regions, layers and/or sections, these elements, components, regions, layers and/or sections should not be limited by these terms. These terms may only be used to distinguish one element, component, region, layer or section from another. Terms such as "first," "second" and "third" when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms "substantially," "approximately" and “about” generally mean within a value or range that can be contemplated by people having ordinary skill in the art. Alternatively, the terms "substantially," "approximately" and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms "substantially," "approximately" or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

One problem faced in semiconductor process development is that in order to avoid certain known issues, different types of cells may not be able to abut each other freely. Transitioning from one type of cell to another type of cell requires padding or sacrifice space, which clearly results in wasted chip area. Therefore, manufacturers are required to provide an improved cell arrangement to minimize the wasted or sacrifice spaces. To minimize wasted space while maintaining the power performance area (PPA) benefits of mixing different types of cells, the manufacturers can group cells of the same type into predefined regions. This method/design confines the transition areas to the boundaries between different types of cell regions.

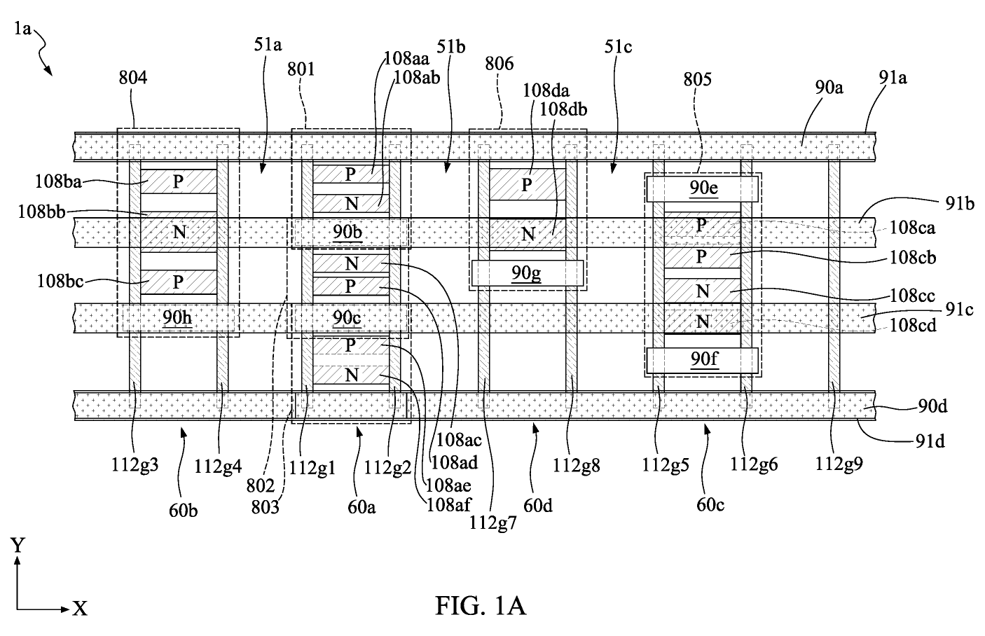

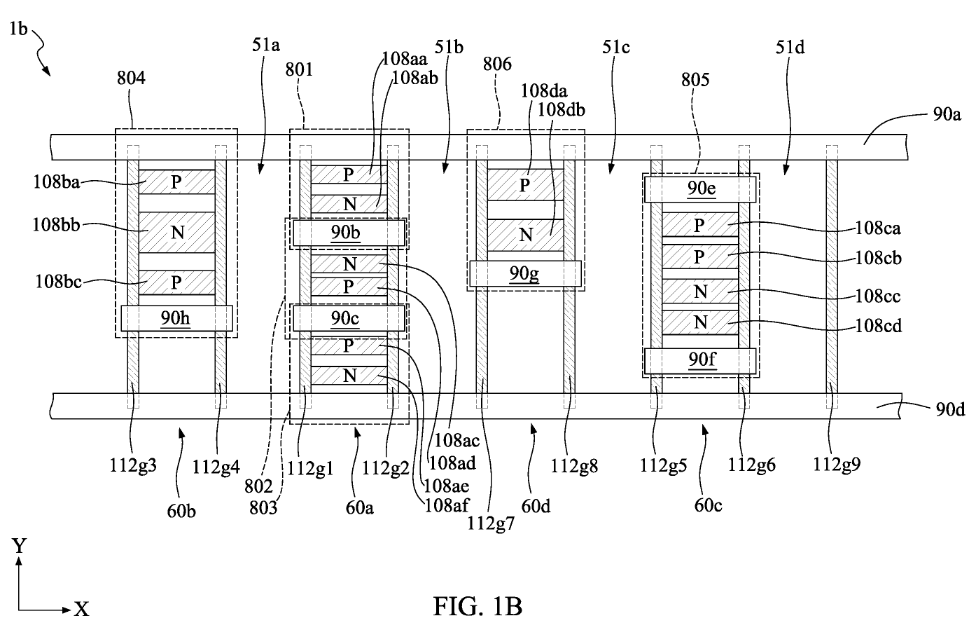

FIG. 1A is a top view of a semiconductor structure 1a in accordance with some embodiments of the present disclosure. The semiconductor structure 1a includes a conductive line 91a, a conductive line 91b, a conductive line 91c, and a conductive line 91d extending in a first direction along the X axis from a top view. In some embodiments, the semiconductor structure 1a includes a first region 60a, a second region 60b, a third region 60c, and a fourth region 60d.

The first region 60a comprises a cell 801, a cell 802, and a cell 803. The cell 801 comprises an isolation structure 90a extending in the first direction along the X axis and an isolation structure 90b extending in the first direction along the X axis from the top view. The cell 801 comprises a gate structure 112g1 extending in a second direction along the Y axis and a gate structure 112g2 extending along the Y axis from the top view. In some embodiments, gate structure 112g1 intersects with the conductive line 91a and the conductive line 91b from the top view. In some embodiments, gate structure 112g1 is respectively perpendicular to the conductive line 91a and the conductive line 91b from the top view. In some embodiments, gate structure 112g2 is respectively perpendicular to the conductive line 91a and the conductive line 91b from the top view. In some embodiments, gate structure 112g1 is respectively orthogonal to the conductive line 91a and the conductive line 91b from the top view. The cell 801 comprises an oxide diffusion (OD) region 108aa and an oxide diffusion region 108ab. In some embodiments, the term “oxide diffusion region” discussed in the present disclosure may also be referred to as an active region. In some embodiments, the oxide diffusion region 108aa is configured for PMOS technology (the work function is a P-work-function) and oxide diffusion region 108ab is configured for NMOS technology (the work function is a N-work-function). The design of the semiconductor structure 1a increases flexibility for the circuit design. Although not depicted in FIG. 1A, there can be several additional gate structures extending along the Y-axis and located between gate structures 112g1 and 112g2. The oxide diffusion regions 108aa and 108ab, which comprise the gate structures 112g1 and 112g2, are controlled by control signals through one or more of the gate structures 112g1, gate structure 112g2, or the additional gate structures (not shown) located between gate structures 112g1 and 112g2.

In some embodiments, any of the gate structures 112g1 and 112g2 can be replaced with dielectric materials or electrical isolation materials. Gate structures 112g1 and 112g2, when replaced with dielectric materials or electrical isolation materials, can be referred to as dummy gate structures. Additionally, if these gate structures are replaced with dielectric materials or electrical isolation materials, they can also be described as continuous polysilicon on oxide diffusion (OD) edge structures, commonly known as CPODE structures. In some embodiments, isolation structures 90a and 90b, along with gate structures 112g1 and 112g2 (whether or not they are replaced with dielectric materials or electrical isolation materials), can be referred to as the boundaries of cell 801.

In some embodiments, the oxide diffusion region 108aa is constructed in such a way that a P-type transistor includes an input from a voltage source or VDD through the conductive line 91a. In some embodiments, the oxide diffusion region 108ab is constructed in such a way that a N-type transistor includes an input from VSS or ground through the conductive line 91b. In some embodiments, the outputs of the P-type and N-type transistors are complementary such that when the input is low, the output is high, and when the input is high, the output is low. Because of this behavior of input and output, in some embodiments, the CMOS circuit output is the inverse of the input. In some embodiments, the cell 801 is configured for a PN region.

The cell 802 comprises the isolation structure 90b extending in the first direction along the X axis and an isolation structure 90c extending in the first direction along the X axis from the top view. The cell 802 comprises gate structure 112g1 extending along the Y axis and gate structure 112g2 extending along the Y axis from the top view. In some embodiments, gate structure 112g1 respectively intersects with the conductive line 91a and the conductive line 91b from the top view. In some embodiments, gate structure 112g2 respectively intersects with the conductive line 91a and the conductive line 91b from the top view. In some embodiments, gate structure 112g1 respectively intersects with the isolation structure 90b and the isolation structure 90c from the top view. In some embodiments, gate structure 112g2 is respectively orthogonal to the isolation structure 90b and the isolation structure 90c from the top view. The cell 802 comprises an oxide diffusion region 108ac and an oxide diffusion region 108ad. In some embodiments, the oxide diffusion region 108ac is configured for NMOS technology (the work function is a N-work-function) and oxide diffusion region 108ad is configured for PMOS technology (the work function is a P-work-function).

Although not depicted in FIG. 1A, there can be several additional gate structures extending along the Y-axis and located between gate structures 112g1 and 112g2. The oxide diffusion regions 108ac and 108ad, which comprise the gate structures 112g1 and 112g2, are controlled by control signals through one or more of the gate structures 112g1, gate structure 112g2, or the additional gate structures (not shown) located between gate structures 112g1 and 112g2.

In some embodiments, any of the gate structures 112g1 and 112g2 can be replaced with dielectric materials or electrical isolation materials. Gate structures 112g1 and 112g2, when replaced with dielectric materials or electrical isolation materials, can be referred to as dummy gate structures. Additionally, if these gate structures are replaced with dielectric materials or electrical isolation materials, they can also be described as continuous polysilicon on oxide diffusion (OD) edge structures, commonly known as CPODE structures. In some embodiments, isolation structures 90b and 90c, along with gate structures 112g1 and 112g2 (whether or not they are replaced with dielectric materials or electrical isolation materials), can be referred to as the boundaries of cell 802. In some embodiments, the oxide diffusion region 108ad is constructed in such a way that a P-type transistor includes input from a voltage source or VDD through the conductive line 91c. In some embodiments, the oxide diffusion region 108ac is constructed in such a way that a N-type transistor includes input from VSS or ground through the conductive line 91b. In some embodiments, the cell 802 is configured for a PN region.

The cell 803 comprises the isolation structure 90c extending along the X axis and an isolation structure 90d extending along the X axis from the top view. The cell 803 comprises gate structure 112g1 extending along the Y axis and gate structure 112g2 extending along the Y axis from the top view. In some embodiments, gate structure 112g1 respectively intersects with the isolation structure 90c and the isolation structure 90d from the top view. In some embodiments, gate structure 112g2 is respectively orthogonal to the isolation structure 90c and the isolation structure 90d from the top view. In some embodiments, gate structure 112g2 is respectively perpendicular to the isolation structure 90c and the isolation structure 90d from the top view. The cell 803 comprises an oxide diffusion region 108ae and an oxide diffusion region 108af. In some embodiments, the oxide diffusion region 108af is configured for NMOS technology (the work function is a N-work-function) and oxide diffusion region 108ae is configured for PMOS technology (the work function is a P-work-function). The oxide diffusion regions 108ae and 108af which comprise the gate structures 112g1 and 112g2 are controlled by the control signals through gate structure 112g1 or 112g2.

In some embodiments, any of the gate structures 112g1 and 112g2 can be replaced with dielectric materials or electrical isolation materials. In some embodiments, isolation structures 90c and 90d, along with gate structures 112g1 and 112g2 (whether or not they are replaced with dielectric materials or electrical isolation materials), can be referred to as the boundaries of cell 803. In some embodiments, the oxide diffusion region 108ae is constructed in such a way that a P-type transistor includes input from a voltage source or VDD through the conductive line 91c. In some embodiments, the oxide diffusion region 108af is constructed in such a way that a N-type transistor includes input from VSS or ground through the conductive line 91d. In some embodiments, the cell 803 is configured for a PN region.

The second region 60b comprises a cell 804. The cell 804 comprises the isolation structure 90a extending along the X axis and the isolation structure 90h extending along the X axis from the top view. The cell 804 comprises a gate structure 112g3 extending along the Y axis and a gate structure 112g4 extending along the Y axis from the top view. In some embodiments, gate structure 112g3 intersects with the conductive line 91a and the conductive line 91c from the top view. In some embodiments, gate structure 112g3 is respectively perpendicular to the conductive line 91a and the conductive line 91c from the top view. In some embodiments, gate structure 112g4 is respectively perpendicular to the conductive line 91a and the conductive line 91c from the top view. In some embodiments, gate structure 112g3 is respectively orthogonal to the conductive line 91a and the conductive line 91c from the top view. The cell 804 comprises an oxide diffusion region 108ba, an oxide diffusion region 108bb, and an oxide diffusion region 108bc. In some embodiments, the oxide diffusion regions 108ba and 108bc are configured for PMOS technology (the work function is a P-work-function) and oxide diffusion region 108bb is configured for NMOS technology (the work function is a N-work-function).

Although not depicted in FIG. 1A, there can be several additional gate structures extending along the Y-axis and located between gate structures 112g3 and 112g4. The oxide diffusion regions 108ba, 108bb, and 108bc, which comprise the gate structures 112g3 and 112g4, are controlled by control signals through one or more of the gate structures 112g3, gate structure 112g4, or the additional gate structures (not shown) located between gate structures 112g3 and 112g4. Both of gate structure 112g4 and gate structure 112g3 intersects with the conductive line 91a and the conductive line 91c from the top view. Both of gate structure 112g4 and gate structure 112g3 intersects with the isolation structure 90a and the isolation structure 90h from the top view. Both of gate structure 112g4 and gate structure 112g3 are respectively perpendicular to the isolation structure 90a and the isolation structure 90h from the top view.

In some embodiments, any of the gate structures 112g3 and 112g4 can be replaced with dielectric materials or electrical isolation materials. In some embodiments, isolation structures 90a and 90h, along with gate structures 112g3 and 112g4 (whether or not they are replaced with dielectric materials or electrical isolation materials), can be referred to as the boundaries of cell 804. In some embodiments, the oxide diffusion regions 108ba and 108bc are constructed in such a way that a P-type transistor includes input from a voltage source or VDD through the conductive lines 91a or 91c. In some embodiments, the oxide diffusion region 108bb is constructed in such a way that a N-type transistor includes input from VSS or ground through the conductive line 91b. In some embodiments, the cell 804 is configured for a PNP region.

In some embodiments, a padding region 51a is adjacent to the first region 60a and the second region 60b. The padding region 51a is disposed between gate structure 112g1 and gate structure 112g4 from the top view. The padding region 51a is a dummy region for separating two active regions (e.g., active regions within the first region 60a and second region 60b). The padding region 51a is a dummy region used to separate two regions with different cell configurations (e.g., cells 801 and 804). In some embodiments, the padding region 51a is used as a sacrifice space. In some embodiments, a distance between gate structure 112g1 and gate structure 112g2 is the same as that between gate structure 112g3 and gate structure 112g4. In some embodiments, a distance between gate structure 112g1 and gate structure 112g2 is the same as a distance between gate structure 112g1 and gate structure 112g4.

The third region 60c comprises a cell 805. The cell 805 comprises an isolation structure 90e extending along the X axis and an isolation structure 90f extending along the X axis from the top view. The cell 805 comprises a gate structure 112g5 extending along the Y axis and a gate structure 112g6 extending along the Y axis from the top view. In some embodiments, gate structure 112g5 intersects with the conductive lines 91a, 91b, 91c, and 91d from the top view. In some embodiments, gate structure 112g5 intersects with the isolation structure 90a, 90e, 90f, and 90d from the top view. In some embodiments, gate structure 112g5 is respectively perpendicular to the conductive line 91a, 91b, 91c, and 91d from the top view. In some embodiments, gate structure 112g6 is respectively perpendicular to the conductive line 91a, 91b, 91c, and 91d from the top view. In some embodiments, gate structure 112g5 is respectively orthogonal to the isolation structure 90a, 90e, 90f, and 90d from the top view. The cell 805 comprises an oxide diffusion region 108ca, an oxide diffusion region 108cb, an oxide diffusion region 108cc, and an oxide diffusion region 108cd. In some embodiments, the oxide diffusion regions 108ca and 108cb are configured for PMOS technology (the work function is a P-work-function) and oxide diffusion regions 108cc and 108cd are configured for NMOS technology (the work function is a N-work-function).

The oxide diffusion regions 108ca, 108cb, 108cc, and 108cd which comprise the gate structures 112g5 and 112g6 are controlled by the control signals through gate structure 112g5 or 112g6. Although not depicted in FIG. 1A, there can be several additional gate structures extending along the Y-axis and located between gate structures 112g5 and 112g6. The oxide diffusion regions 108ca, 108cb, 108cc, and 108cd, which comprise the gate structures 112g5 and 112g6, are controlled by control signals through one or more of the gate structures 112g5, gate structure 112g6, or the additional gate structures (not shown) located between gate structures 112g5 and 112g6.

In some embodiments, any of the gate structures 112g5 and 112g6 can be replaced with dielectric materials or electrical isolation materials. In some embodiments, isolation structures 90eand 90f, along with gate structures 112g5 and 112g6 (whether or not they are replaced with dielectric materials or electrical isolation materials), can be referred to as the boundaries of cell 805. In some embodiments, the oxide diffusion regions 108ca, 108cb are constructed in such a way that a P-type transistor includes input from a voltage source or VDD through the conductive lines 91a or 91c. In some embodiments, the oxide diffusion regions 108cc and 108cd are constructed in such a way that a N-type transistor includes input from VSS or ground through the conductive line 90b. In some embodiments, the cell 805 is configured for a PPNN region. In some embodiments, a padding region 51b is adjacent to the first region 60a and the second region 60b. In some embodiments, a projection area of the isolation structure 90e falls within a projection area between the isolation structure 90a and the conductive line 91b from the top view. In some embodiments, a projection area of the isolation structure 90e falls within a projection area between the conductive line 91a and the conductive line 91b from the top view.

The fourth region 60d comprises a cell 806. The cell 806 comprises an isolation structure 90a extending along the X axis and an isolation structure 90g extending along the X axis from the top view. The cell 806 comprises a gate structure 112g7 extending along the Y axis and a gate structure 112g8 extending along the Y axis from the top view. In some embodiments, gate structure 112g7 intersects with the conductive lines 91a, 91b, 91c, and 91d from the top view. In some embodiments, gate structure 112g7 intersects with the isolation structure 90a, 90g, and 90d from the top view. In some embodiments, a cell height of the cell 806 is greater than a cell height of the cell 801 and is less than a cell height of a sum of the cell 801 and the cell 802. In some embodiments, the cell height of the cell 806 is approximately 1.5 times that of the cell 801. In some embodiments, the cell height of the cell 806 is approximately 1.5 times that of the cell 802.

In some embodiments, gate structure 112g7 is respectively perpendicular to the conductive line 91a, 91b, 91c, and 91d from the top view. In some embodiments, gate structure 112g8 is respectively perpendicular to the conductive line 91a, 91b, 91c, and 91d from the top view. In some embodiments, gate structure 112g7 is respectively orthogonal to the isolation structure 90a, 90g, and 90d from the top view. The cell 806 comprises an oxide diffusion region 108da and an oxide diffusion region 108db. In some embodiments, the oxide diffusion region 108da is configured for PMOS technology (the work function is a P-work-function) and oxide diffusion region 108db is configured for NMOS technology (the work function is a N-work-function). The oxide diffusion regions 108da and 108db which comprise the gate structures 112g7 and 112g8 are controlled by the control signals through gate structure 112g7 or 112g8. In some embodiments, any of the gate structures 112g7 and 112g8 can be replaced with dielectric materials or electrical isolation materials. In some embodiments, the oxide diffusion region 108db is constructed in such a way that a P-type transistor includes input from a voltage source or VDD through the conductive lines 91a or 91c. In some embodiments, the oxide diffusion region 108db is constructed in such a way that a N-type transistor includes input from VSS or ground through the conductive line 90b. In some embodiments, the cell 806 is configured for a PN region.

The padding region 51b is disposed between gate structure 112g2 and gate structure 112g7 from the top view. The padding region 51b is a dummy region for separating two active regions (e.g., active regions within first region 60a and fourth region 60d). The padding region 51b is a dummy region used to separate two regions with different cell configurations (e.g., cells 801 and 806). In some embodiments, the padding region 51b is used as a sacrifice space. In some embodiments, the padding region 51c is disposed between gate structure 112g5 and gate structure 112g8 from the top view. The padding region 51cis a dummy region for separating two active regions (e.g., active regions within third region 60c and fourth region 60d). The padding region 51c is a dummy region used to separate two regions with different cell configurations (e.g., cells 805 and 806). In some embodiments, the padding region 51c is used as a sacrifice space.

In some embodiments, a projection area of the isolation structure 90g falls between a projection area of the conductive line 91b and a projection area of the conductive line 91c from the top view. In some embodiments, a projection area of the oxide diffusion region 108da falls between a projection area of the conductive line 91a and a projection area of the conductive line 91b from the top view. A distance between gate structure 112g3 and gate structure 112g4 is the same as a distance between gate structure 112g8 and gate structure 112g5. A cell height of the cell 804 is a sum of a cell height of the cell 801 and a cell height of the cell 802. In some embodiments, regarding the unit cells of one function type and other oxide diffusion unit cells of another different function type, differences in the position/dimensions of the oxide diffusion regions and the related implant region are important. As a result, some additional padding spaces are sacrificed to accommodate the transition between two different function types of unit cells. These additional padding/sacrifice spaces are minimized by integrating units with the same function in the same region. In some embodiments, the conductive line 91b passes through the cell 801, cell 804, cell 805, and cell 806 from the top view. In some embodiments, a projection of the conductive line 91b does not overlap with a projection of an upper cell boundary of the cell 801 (e.g., the isolation structure 90a), the cell 804 (e.g., the isolation structure 90a), the cell 805 (e.g., the isolation structure 90e), and the cell 806 (e.g., the isolation structure 90a). In some embodiments, a projection area of the conductive line 91b falls within a projection area of a lower cell boundary of the cell 801 (e.g., the isolation structure 90b). In some embodiments, a projection area of the conductive line 91b overlap with a projection area of the oxide diffusion region 108db of the cell 806.

FIG. 1B is a top view of a semiconductor structure 1b in accordance with some embodiments of the present disclosure. The semiconductor structure 1b is similar to the semiconductor structure 1a, other than no including the conductive lines 91a to 91d. The semiconductor structure 1b includes a first region 60a, a second region 60b, a third region 60c, and a fourth region 60d. In some embodiments, a cell poly pitch (CPP) of the region 60a is substantially the same as the cell poly pitch of the region 60b. The cell poly pitch of the region 60c is substantially the same as the cell poly pitch of the region 60d. The cell poly pitch of the region 60b is substantially the same as the cell poly pitch of the region 60c. In some embodiments, the cell poly pitch is defined between two adjacent gate structures (e.g., between gate structure 112g3 and gate structure 112g4).

In some embodiments, the cells 801 to 803 are respectively configured for a PN region. In some embodiments, the cell 804 is configured for a PNP region. In some embodiments, the cell 806 is configured for a PN region. In some embodiments, the cell 805 comprises four oxide diffusion regions configured for a PPNN region.

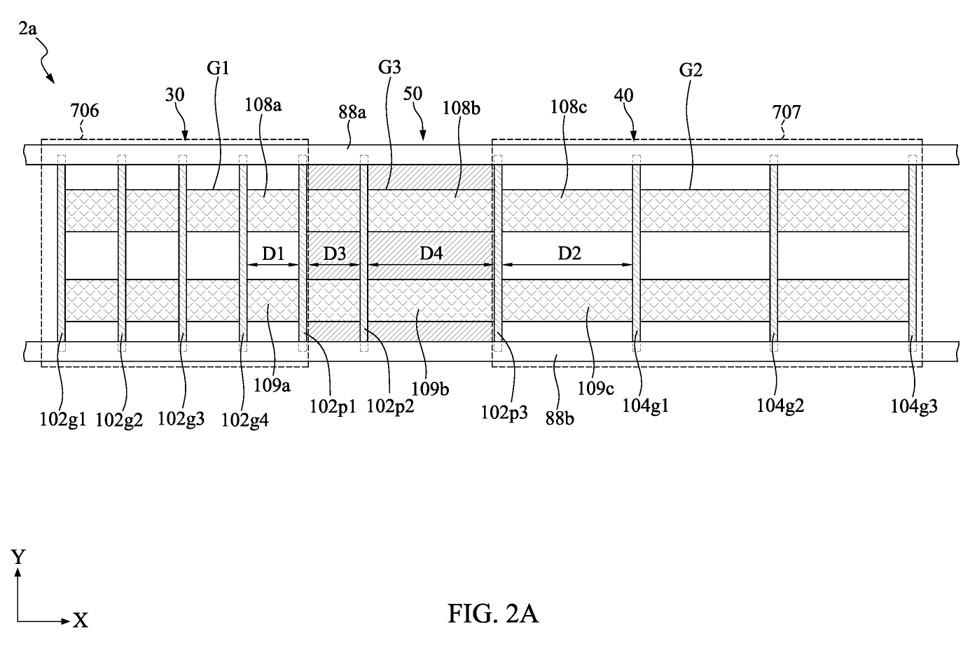

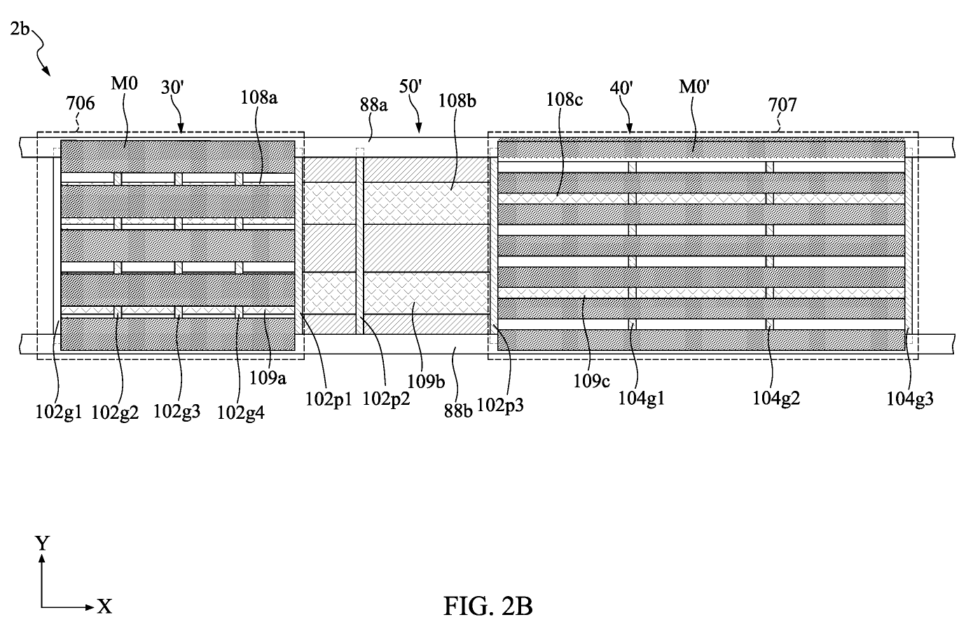

FIG. 2A is a top view of a semiconductor structure 2a in accordance with some embodiments of the present disclosure. The semiconductor structure 2a includes a region 30 and a region 40, and a padding region 50 adjacent to the region 30 and the region 40.

The region 30 comprises a cell 706. The cell comprises an isolation structure 88a, an isolation structure 88b, a gate structure 102g4, and a dummy gate structure 102p1. Gate structure 102g4 is spaced apart from the dummy gate structure 102p1 by a first distance D1 from a top view. The region 40 comprises a cell 707. The cell 707 comprises the isolation structure 88a, the isolation structure 88b, a gate structure 104g1, and a dummy gate structure 102p3. Gate structure 104g1 is spaced apart from the dummy gate structure 102p3 by a distance D2 from the top view. The first distance is different from the second distance. The padding region 50 is disposed between a dummy gate structure 102p1 and a dummy gate structure 102p3 from the top view.

The cell 706 comprises oxide diffusion regions 108a and 109a. The cell 707 comprises oxide diffusion regions 108c and 109c. An upper edge G1 of the oxide diffusion region 108a is aligned with an upper edge G2 of the oxide diffusion region 108c from the top view. The padding region 50 comprises dummy gate structures 102p1, 102p2, and 102p3. A distance D3 between dummy gate structure 102p1 and dummy gate structure 102p2 is different from a distance D4 between dummy gate structure 102p2 and dummy gate structure 102p3 from the top view. A lateral width of the oxide diffusion region 108a is substantially the same as a lateral width of the oxide diffusion region 108c from the top view. The padding region 50 comprises a dummy oxide diffusion region 108b. An upper edge G3 of the dummy oxide diffusion region 108b is aligned with an upper edge G1 of the oxide diffusion region 108a from the top view. A lateral width of the dummy oxide diffusion region 108b is substantially the same as a lateral width of the oxide diffusion region 108c from the top view. A lateral width of the dummy oxide diffusion region 108a is substantially the same as a lateral width of the oxide diffusion region 108b from the top view. The padding region 50 comprises a dummy gate structure 102p2.

A distance D3 between the dummy gate structure 102p1 and the dummy gate structure 102p2 is different from a fourth distance D4 between the dummy gate structure 102p2 and the dummy gate structure 102p3 from the top view. In order to maintain the same cell structure to prevent layer alignment issues, the two aligned isolation structures 88a and 88b are used to separate two different cell structures (e.g., regions 30 and 40) having different cell poly pitches (CPPs). The cell poly pitch is defined between two adjacent gate structures (e.g., between gate structure 102g2 and gate structure 102g3). Since the unit cell height of the regions 30 and 40 remains unchanged, only one padding area is needed for the transition of two different cell structures (e.g., regions 30 and 40). In some embodiments, there is no padding area between regions 30 and 40 (not shown).

FIG. 2B is a top view of a semiconductor structure 2b in accordance with some embodiments of the present disclosure. The semiconductor structure 2b is similar to the semiconductor structure 2, other than the conductive lines. The semiconductor structure 2b includes a region 30', a region 40', and the padding area 50', and a padding region 50' adjacent to the region 30' and the region 40'. A first plurality of conductive lines M0 is disposed above the region 30' and parallel to the isolation structure 88a from the top view. A second plurality of conductive lines M0' is disposed above the region 40' and parallel to the isolation structure 88a. A first number of the first plurality of conductive lines M0 is different from a second number of the second plurality of conductive lines M0'. The conductive lines M0 or M0' design scheme will impact the performance and the area size of cells with different functions. If the number of conductive lines M0 is increased and the cell height is not changed, the area of the cell with the same function will be decreased. The padding area 50' can be saved by integrating the units with the same function in the same region. In some embodiments, the cells in the region 30' have a first function and the cells in the region 40' may have a second function different from the first function. In some embodiments, the conductive lines M0 or M0' can be connected to a voltage source or voltage VDD. In some embodiments, the conductive lines M0 or M0' can be connected to a voltage VSS or ground.

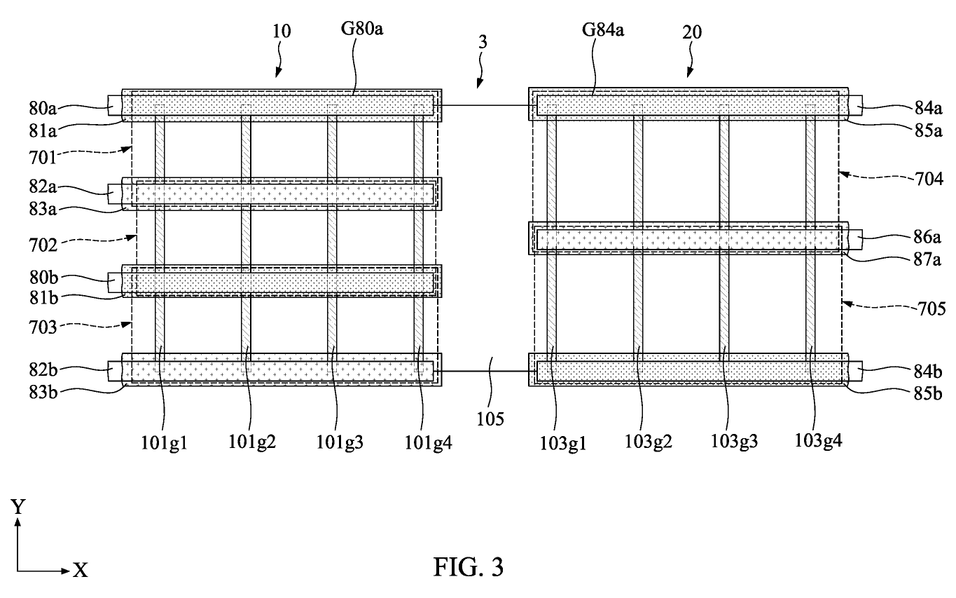

FIG. 3 is a top view of a semiconductor structure 3 in accordance with some embodiments of the present disclosure. The semiconductor structure 3 includes a region 10, a region 20, and a padding region 105. The region 10 comprises a cell 701, a cell 702, and a cell 703. The cell 701 comprises an isolation structure 80a and an isolation structure 82a. The cell 701 comprises a conductive line 81a and a conductive line 83a. The cell 701 comprises gate structures 101g1 to 101g4 extending in the second direction along the Y axis from the top view. The cell 702 comprises an isolation structure 82a and an isolation structure 80b. The cell 702 comprises the conductive line 83a and a conductive line 81b. The cell 702 comprises gate structures 101g1 to 101g4 extending along the Y axis from the top view. The cell 703 comprises the isolation structure 80b and an isolation structure 82b. The cell 703 comprises the conductive line 81b and a conductive line 83b. The cell 703 comprises gate structures 101g1 to 101g4 extending along the Y axis from the top view. In some embodiments, any of the gate structures 101g1 and 101g4 can be replaced with dielectric materials or electrical isolation materials. In some embodiments, the conductive lines 81a and 81b are connected to a voltage source or voltage VDD. In some embodiments, the conductive lines 82a and 82b are connected to a voltage VSS or ground.

The region 20 comprises a cell 704 and a cell 705. The cell 704 comprises an isolation structure 84a and an isolation structure 86a. The cell 704 comprises a conductive line 85a and a conductive line 87a. The cell 705 comprises the isolation structure 86a and an isolation structure 84b. The cell 705 comprises the conductive line 87a and a conductive line 85b. The padding region 105 is adjacent to the region 10 and the region 20. The padding region 105 is disposed between the region 10 and the region 20 from the top view. In some embodiments, any of the gate structures 103g1 and 103g4 can be replaced with dielectric materials or electrical isolation materials. In some embodiments, the conductive lines 84 and 84b are connected to a voltage source or voltage VDD. In some embodiments, the conductive line 87a is connected to a voltage VSS or ground. An upper edge G80a of the isolation structure 80a is aligned with an upper edge G84a of the isolation structure 84a.

A cell height of the region 10 is different from a cell height of the region 20. In some embodiments, the cell height of the region 10 is less than a cell height of the region 20. In some embodiments, the cell poly pitch (CPP) of the region 10 is substantially the same as the cell poly pitch of the region 20. In some embodiments, a distance between gate structure 101g3 and gate structure 101g4 is substantially the same as a distance between gate structure 103g1 and gate structure 103g2. In some embodiments, a distance between gate structure 101g3 and gate structure 101g4 is substantially the same as a distance between gate structure 101g4 and gate structure 103g1. In some embodiments, the cell poly pitch of the region 10 is substantially the same as the lateral width of the padding region 105. The padding region 105 is disposed between gate structure 101g4 of the region 10 and gate structure 103g1 of the region 20 from the top view.

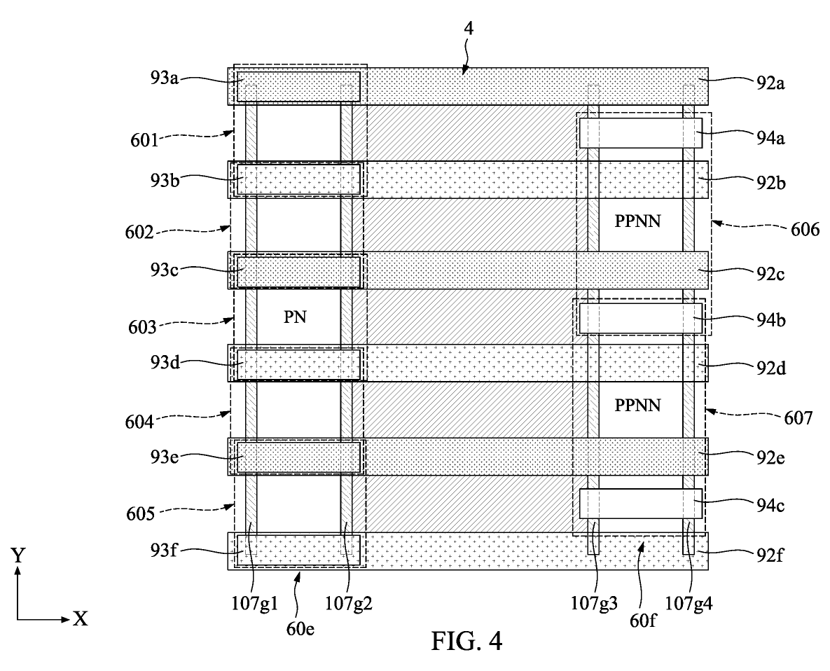

FIG. 4 is a top view of a semiconductor structure 4 in accordance with some embodiments of the present disclosure. The semiconductor structure 4 includes conductive lines 92a to 92f extending along the X axis from a top view. In some embodiments, the semiconductor structure 4 includes a region 60e and a region 60f. The region 60e comprises cells 601 to 605. The cell 601 comprises an isolation structure 93aand an isolation structure 93b extending along the X axis from the top view. The cell 601 comprises a gate structure 107g1 extending along the Y axis and a gate structure 107g2 extending along the Y axis from the top view. In some embodiments, gate structure 107g1 is respectively perpendicular to the conductive line 93a and the conductive line 93b from the top view. In some embodiments, the cell 601 comprises two oxide diffusion regions configured for a PN region. The cell 601 is similar to the cell 801. In some embodiments, the cells 602 to 605 are similar to the cell 601.

The region 60f comprises two cells 606 and 607. The cell 606 comprises an isolation structure 94a extending along the X axis and an isolation structure 94b extending along the X axis from the top view. The cell606 comprises a gate structure 107g3 extending along the Y axis and a gate structure 107g4 extending along the Y axis from the top view. In some embodiments, gate structure 107g3 is respectively perpendicular to the conductive line 92a, 92b, 92c, 92d, and 92f from the top view. In some embodiments, the cell 606 comprises four oxide diffusion regions configured for a PPNN region. The cell 606 is similar to the cell 805. In some embodiments, the cell 607 is similar to the cell 606. In some embodiments, a projection area of the isolation structure 94a falls within a projection area between a projection area of the conductive line 92a and a projection area of the conductive line 92b from the top view. In some embodiments, a projection area of the isolation structure 94b falls within a projection area between a projection area of the conductive line 92c and a projection area of the conductive line 92d from the top view. The padding region 105a is disposed between gate structure 107g2 and gate structure 107g3 from the top view. In some embodiments, the conductive lines 92a, 92c, and 92e are connected to a voltage source or voltage VDD. In some embodiments, the conductive lines 92b, 92d, and 92f are connected to a voltage VSS or ground. In some embodiments, a distance between gate structure 107g1 and gate structure 107g2 is substantially the same as a distance between gate structure 107g3 and gate structure 107g4. In some embodiments, a distance between gate structure 107g1 and gate structure 107g2 is less than a distance between gate structure 107g2 and gate structure 107g3.

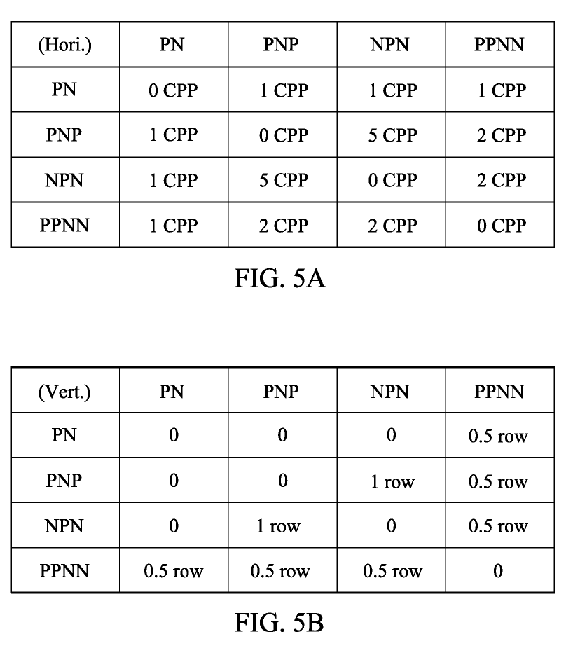

FIGS. 5A and 5B are tables showing the padding distance between different cell structures in accordance with some embodiments of the present disclosure. Referring to FIG. 5A, the padding distance between different function types of cells is shown on the table. In some embodiments, along the X axis (horizontally), a padding distance between one PN cell region and another PN cell region can be 0 cell poly pitch (CPP). In some embodiments, along the X axis (horizontally), a padding distance between one PN cell region and a PNP cell region can be 1 CPP. In some embodiments, horizontally, a padding distance between one PN cell region and a NPN cell region can be 1 CPP. In some embodiments, horizontally, a padding distance between one PN cell region and a PPNN cell region can be 1 CPP. In some embodiments, horizontally, a padding distance between one PNP cell region and a NPN cell region can be 5 CPPs. In some embodiments, horizontally, a padding distance between one PNP cell region and a PPNN cell region can be 2 CPPs.

Referring to FIG. 5B, along the Y axis (vertically), a distance between one PN cell region and another PN cell region can be zero row. For example, two PN cell regions can be adjacently disposed without a padding region along the Y axis (vertically). In some embodiments, along the Y axis (vertically), a distance between one PN cell region and a PPNN cell region can be 0.5 row (e.g., corresponding to 0.5 cell height). In some embodiments, along the Y axis (vertically), a distance between one PNP cell region and a PN cell region can be zero row. In some embodiments, along the Y axis (vertically), a distance between one PNP cell region and a NPN cell region can be one row (e.g., corresponding to one cell height).

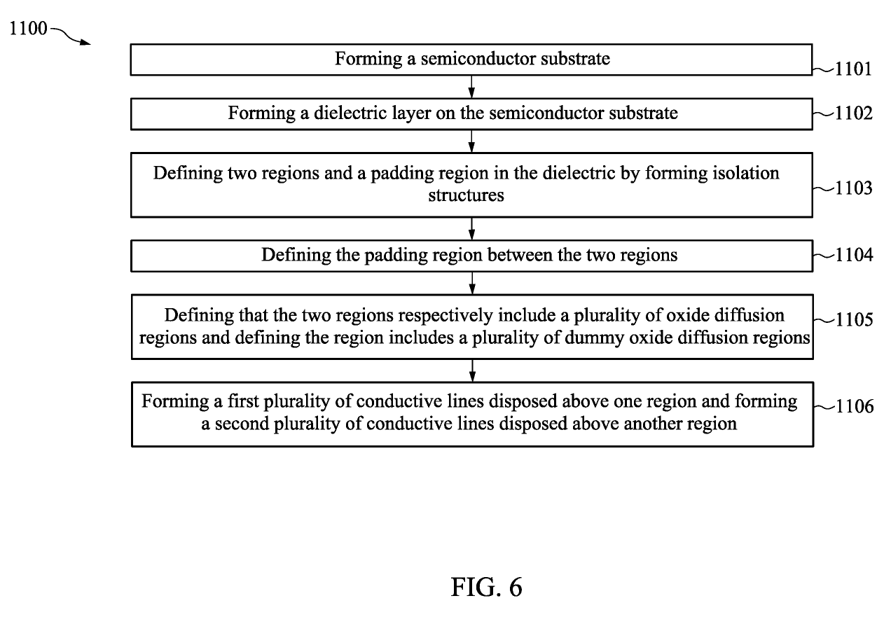

FIG. 6 is a flowchart of an embodiment of a method 1100 of manufacturing a semiconductor device 2b in accordance with some embodiments of the present disclosure. In some embodiments, the method may include various operations for manufacturing the semiconductor device 2b. The method 1100 includes forming a semiconductor substrate (operation 1101). The method 1100 includes forming a dielectric layer on the semiconductor substrate (operation 1102). The method 1100 includes defining two regions 30' and region 40', and a padding region 50' in the dielectric by forming isolation structures 88a and 88b (operation 1103). The method 1100 further includes defining the padding region 50' between the two regions 30' and 40' (operation 1104). The method 1100 further includes defining that the two regions 30' and 40' respectively include a plurality of oxide diffusion regions and defining the region 50' includes a plurality of dummy oxide diffusion regions (operation 1105). The method 1100 further includes forming a first plurality of conductive lines M0 disposed above one region 30' and forming a second plurality of conductive lines M0' disposed above another region 40' (operation 1106). In some embodiments, the cells in the region 30' have a first function and the cells in the region 40' may have a second function different from the first function. The present disclosure reduces the padding area 50' by integrating the units with the same function in the same region. The method or semiconductor device in accordance with some embodiments of the present disclosure includes, but is not limited to, the mentioned processes.

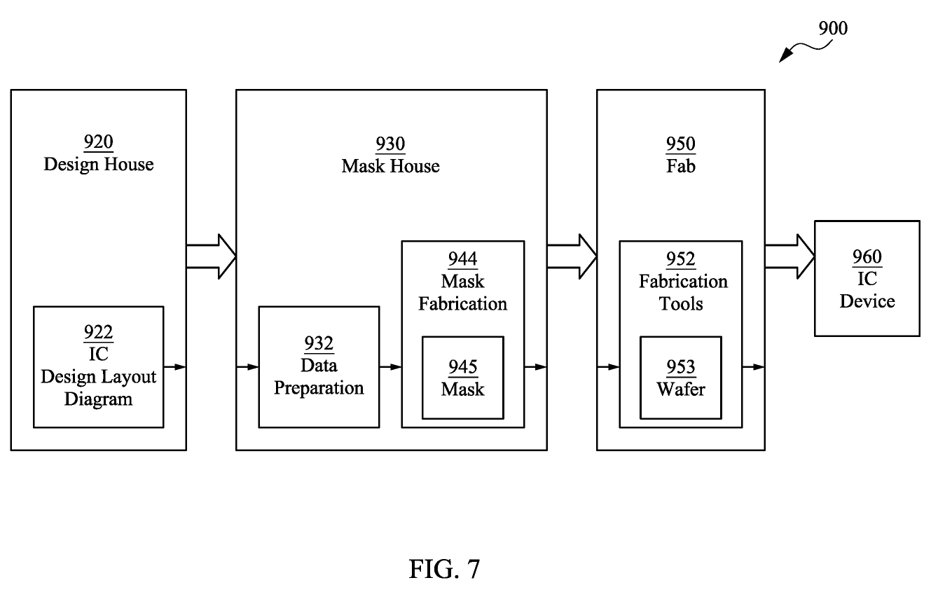

FIG. 7 is a block diagram of an integrated circuit (IC) manufacturing system 900, and an IC manufacturing flow associated therewith, in accordance with some embodiments. In some embodiments, based on a layout diagram, at least one of (A) one or more semiconductor masks or (B) at least one component in a layer of a semiconductor integrated circuit is fabricated using manufacturing system 900.

In some embodiments, in FIG. 7, IC manufacturing system 900 includes entities, such as a design house 920, a mask house 930, and an IC manufacturer/fabricator (“fab”) 950, that interact with one another in the design, development, and manufacturing cycles and/or services related to manufacturing an IC device 960. Additionally or alternatively, the entities in system 900 are connected by a communications network. In some embodiments, the communications network is a single network. In some embodiments, the communications network is a variety of different networks, such as an intranet and the Internet. Additionally or alternatively, the communications network includes wired and/or wireless communication channels. In some embodiments, each entity interacts with one or more of the other entities and provides services to and/or receives services from one or more of the other entities. In some embodiments, two or more of design house 920, mask house 930, and IC fab 950 are owned by a single larger company. In some embodiments, two or more of design house 920, mask house 930, and IC fab 950 coexist in a common facility and use common resources.

In some embodiments, design house (or design team) 920 generates an IC design layout diagram 922. Additionally or alternatively, IC design layout diagram 922 includes various geometrical patterns designed for an IC device 960. In some embodiments, the geometrical patterns correspond to patterns of metal, oxide, or semiconductor layers that make up the various components of IC device 960 to be fabricated. Additionally or alternatively, the various layers combine to form various IC features. For example, a portion of IC design layout diagram 922 includes various IC features, such as an active region, gate terminal, source terminal and drain terminal, metal lines or vias of an interlayer interconnection, and openings for bonding pads, to be formed in a semiconductor substrate (such as a silicon wafer) and various material layers on the semiconductor substrate. In some embodiments, design house 920 implements a proper design procedure to form IC design layout diagram 922. Additionally or alternatively, the design procedure includes one or more of logic design, physical design, or place and route. In some embodiments, IC design layout diagram 922 is presented in one or more data files having information of the geometrical patterns. For example, IC design layout diagram 922 can be expressed in a GDSII file format or DFII file format.

In some embodiments, mask house 930 includes mask data preparation 932 and mask fabrication 944. Additionally or alternatively, mask house 930 uses IC design layout diagram 922 to manufacture one or more masks 945 to be used for fabricating the various layers of IC device 960 according to IC design layout diagram 922. In some embodiments, mask house 930 performs mask data preparation 932, where IC design layout diagram 922 is translated into a representative data file (“RDF”). Additionally or alternatively, mask data preparation 932 provides the RDF to mask fabrication 944. In some embodiments, mask fabrication 944 includes a mask writer. Additionally or alternatively, a mask writer converts the RDF to an image on a substrate, such as a mask (reticle) 945 or a semiconductor wafer 953. In some embodiments, the design layout diagram 922 is manipulated by mask data preparation 932 to comply with particular characteristics of the mask writer and/or requirements of IC fab 950. Additionally or alternatively, in FIG. 9, mask data preparation 932 and mask fabrication 944 are illustrated as separate elements. In some embodiments, mask data preparation 932 and mask fabrication 944 are collectively referred to as mask data preparation.

In some embodiments, mask data preparation 932 includes optical proximity correction (OPC) which uses lithography enhancement techniques to compensate for image errors, such as those that arise from diffraction, interference, other process effects and the like. Additionally or alternatively, OPC adjusts IC design layout diagram 922. In some embodiments, mask data preparation 932 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 932 includes a mask rule checker (MRC) that checks the IC design layout diagram 922 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 922 to compensate for limitations during mask fabrication 944, which undoes part of the modifications performed by OPC in order to meet mask creation rules.

In some embodiments, mask data preparation 932 includes lithography process checking (LPC) that simulates processing that will be implemented by IC fab 950 to fabricate IC device 960. Additionally or alternatively, LPC simulates this processing based on IC design layout diagram 922 to create a simulated manufactured device, such as IC device 960. In some embodiments, the processing parameters in LPC simulation include parameters associated with various processes of the IC manufacturing cycle, parameters associated with tools used for manufacturing the IC, and/or other aspects of the manufacturing process. LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are repeated to further refine IC design layout diagram 922.

In some embodiments, the foregoing description of mask data preparation 932 has been simplified for the purposes of clarity. In some embodiments, mask data preparation 932 includes additional features such as a logic operation (LOP) to modify the IC design layout diagram 922 according to manufacturing rules. Additionally, the processes applied to IC design layout diagram 922 during mask data preparation 932 are executed in a variety of different orders.

In some embodiments, after mask data preparation 932 and during mask fabrication 944, a mask 945 or a group of masks 945 are fabricated based on the modified IC design layout diagram 922. In some embodiments, mask fabrication 944 includes performing one or more lithographic exposures based on IC design layout diagram 922. In some embodiments, an electron-beam (e-beam) or a mechanism of multiple e-beams is used to form a pattern on a mask (photomask or reticle) 945 based on the modified IC design layout diagram 922. Additionally or alternatively, mask 945 is formed in various technologies. In some embodiments, mask 945 is formed using binary technology. In some embodiments, a mask pattern includes opaque regions and transparent regions. Additionally or alternatively, a radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 945 includes a transparent substrate (e.g., fused quartz) and an opaque material (e.g., chromium) coated in the opaque regions of the binary mask. In another example, mask 945 is formed using a phase shift technology. In a phase shift mask (PSM) version of mask 945, various features in the pattern formed on the phase shift mask are configured to have proper phase difference to enhance the resolution and imaging quality. In various examples, the phase shift mask is attenuated PSM or alternating PSM. Additionally or alternatively, the masks generated by mask fabrication 944 are used in a variety of processes. For example, such masks can be used in an ion implantation process to form various doped regions in semiconductor wafer 953, in an etching process to form various etching regions in semiconductor wafer 953, and/or in other suitable processes.

In some embodiments, IC fab 950 is an IC fabrication business that includes one or more manufacturing facilities for the fabrication of a variety of different IC products. In some embodiments, IC fab 950 is a semiconductor foundry. For example, there can be a manufacturing facility for the front end fabrication of a plurality of IC products (front-end-of-line (FEOL) fabrication), while a second manufacturing facility provides the back end fabrication for the interconnection and packaging of the IC products (back-end-of-line (BEOL) fabrication), and a third manufacturing facility provides other services for the foundry business.

In some embodiments, IC fab 950 includes fabrication tools 952 configured to execute various manufacturing operations on semiconductor wafer 953 such that IC device 960 is fabricated in accordance with the masks, e.g. mask 945. In various embodiments, fabrication tools 952 include one or more of a wafer stepper, an ion implanter, a photoresist coater, a process chamber, e.g. a CVD chamber or LPCVD furnace, a CMP system, a plasma etch system, a wafer cleaning system, or other manufacturing equipment capable of performing one or more suitable manufacturing processes as discussed herein.

In some embodiments, IC fab 950 uses mask(s) 945 fabricated by mask house 930 to fabricate IC device 960. Additionally or alternatively, IC fab 950 at least indirectly uses IC design layout diagram 922 to fabricate IC device 960. In some embodiments, semiconductor wafer 953 is fabricated by IC fab 950 using mask(s) 945 to form IC device 960. In some embodiments, the IC fabrication includes performing one or more lithographic exposures based at least indirectly on IC design layout diagram 922. In some embodiments, semiconductor wafer 953 includes a silicon substrate or other proper substrate having material layers formed thereon. Additionally or alternatively, semiconductor wafer 953 further includes one or more of various doped regions, dielectric features, multilevel interconnects, and the like (formed in subsequent manufacturing steps).

According to some embodiments, a semiconductor structure comprises a first conductive line, a second conductive line, and a third conductive line extending in a first direction from a top view. The semiconductor device comprises a first region, a second cell, and padding region. The first region comprises a first cell comprising a first isolation structure and a second isolation structure extending in the first direction, and a first gate structure and a second gate structure extending in a second direction from the top view, wherein the first gate structure intersects with the first conductive line and a second conductive line from the top view. The first region comprises a second cell comprising the second isolation structure, a third isolation structure extending in the first direction, the first gate structure, and the second gate structure, wherein the first gate structure intersects with the second conductive line and the third conductive line from the top view. The second region comprises a third cell comprising the first isolation structure, a fourth isolation structure extending in the first direction, and a third gate structure and a fourth gate structure extending in the second direction, wherein both of the third gate structure and the fourth gate structure intersects with the first conductive line and the fourth isolation structure from the top view. The padding region is adjacent to the first region and the second region and disposed between the first gate structure and the third gate structure from the top view.

According to some embodiments, a semiconductor structure comprises a first region, a second region, and a padding region. The first region comprises a first cell comprising a first isolation structure, a second isolation structure, a first gate structure, and a first dummy gate structure. The first gate structure is spaced apart from the first dummy gate structure by a first distance from a top view. The second region comprises a second cell comprising the first isolation structure, the second isolation structure, a second gate structure, and a second dummy gate structure. The second gate structure is spaced apart from the second dummy gate structure by a second distance from the top view, wherein the first distance is different from the second distance. The padding region is adjacent to the first region and the second region and disposed between the first dummy gate structure and the second dummy gate structure from the top view.

According to some embodiments, a semiconductor structure comprises a first region, a second region, and a padding region. The first region comprises a first cell comprising a first isolation structure and a second isolation structure; a second cell comprising the second isolation structure and a third isolation structure; and a third cell comprising the third isolation structure and a fourth isolation structure. The second region comprises a fourth cell comprising a fifth isolation structure and a sixth isolation structure; and a fifth cell comprising the sixth isolation structure and a seventh isolation structure. The padding region is adjacent to the first region and the second region and disposed between the first region and the second region from the top view.

The methods and features of the present disclosure have been sufficiently described in the examples and descriptions provided. It should be understood that any modifications or changes without departing from the spirit of the present disclosure are intended to be covered in the protection scope of the present disclosure.

Moreover, the scope of the present application is not intended to be limited to the particular embodiments of the process, machine, manufacture, and composition of matter, means, methods and steps described in the specification. As those skilled in the art will readily appreciate from the present disclosure, processes, machines, manufacture, composition of matter, means, methods or steps presently existing or later to be developed, that perform substantially the same function or achieve substantially the same result as the corresponding embodiments described herein, may be utilized according to the present disclosure.

Accordingly, the appended claims are intended to include within their scope: processes, machines, manufacture, compositions of matter, means, methods or steps. In addition, each claim constitutes a separate embodiment, and the combination of various claims and embodiments are within the scope of the present disclosure.

What is claimed is:

1. A semiconductor structure comprising:
a first conductive line, a second conductive line, and a third conductive line extending in a first direction from a top view;
a first region comprising:
a first cell comprising a first isolation structure and a second isolation structure extending in the first direction, and a first gate structure and a second gate structure extending in a second direction from the top view, wherein the first gate structure intersects with the first conductive line and a second conductive line from the top view;
a second cell comprising the second isolation structure, a third isolation structure extending in the first direction, the first gate structure, and the second gate structure, wherein the first gate structure intersects with the second conductive line and the third conductive line from the top view;
a second region comprising:
a third cell comprising the first isolation structure, a fourth isolation structure extending in the first direction, and a third gate structure and a fourth gate structure extending in the second direction, wherein both of the third gate structure and the fourth gate structure intersects with the first conductive line and the fourth isolation structure from the top view;
a padding region adjacent to the first region and the second region and disposed between the first gate structure and the third gate structure from the top view.

2. The semiconductor structure of claim 1, further comprising:
a fourth region comprising:
a fourth cell comprising the first isolation structure, a fifth isolation structure extending in the first direction, and a fifth gate structure and a sixth gate structure extending in the second direction, wherein the fifth gate structure and the sixth gate structure intersects with the first conductive line from the top view, wherein a cell height of the fourth cell is greater than a cell height of the first cell and is less than a cell height of a sum of the first cell and the second cell.

3. The semiconductor structure of claim 2, further comprising a second padding region adjacent to the first region and the fourth region and disposed between the second gate structure and the fifth gate structure from the top view.

4. The semiconductor structure of claim 2, wherein the cell height of the fourth cell is approximately 1.5 times that of the first cell.

5. The semiconductor structure of claim 2, wherein a projection area of the fourth isolation structure falls between a projection area of the second conductive line and a projection area of the third conductive line from the top view.

6. The semiconductor structure of claim 5, further comprising:
a fifth region comprising:
a fifth cell comprising a sixth isolation structure and a seventh isolation structure extending in the first direction, and a seven gate structure and an eighth gate structure extending in the second direction, and
wherein a projection area of the sixth isolation structure falls within a projection area between the first isolation structure and the second conductive line from the top view.

7. The semiconductor structure of claim 2, wherein a first distance between the first gate structure and a second gate structure is the same as a second distance between the third gate structure and the fourth gate structure.

8. The semiconductor structure of claim 2, wherein a cell height of the third cell is a sum of a cell height of the first cell and a cell height of the second cell.

9. A semiconductor structure comprising:
a first region comprising:
a first cell comprising a first isolation structure, a second isolation structure, a first gate structure, and a first dummy gate structure, wherein the first gate structure is spaced apart from the first dummy gate structure by a first distance from a top view;
a second region comprising:
a second cell comprising the first isolation structure, the second isolation structure, a second gate structure, and a second dummy gate structure, wherein the second gate structure is spaced apart from the second dummy gate structure by a second distance from the top view, wherein the first distance is different from the second distance; and
a padding region adjacent to the first region and the second region and disposed between the first dummy gate structure and the second dummy gate structure from the top view.

10. The semiconductor structure of claim 9, wherein the first cell comprises a first oxide diffusion region and the second cell comprises a second oxide diffusion region and wherein an upper edge of the first oxide diffusion region is aligned with an upper edge of the second oxide diffusion region from the top view.

11. The semiconductor structure of claim 10, wherein the padding region comprises a third dummy gate structure, wherein a third distance between the first dummy gate structure and the third dummy gate structure is different from a fourth distance between the third dummy gate structure and the second dummy gate structure from the top view.

12. The semiconductor structure of claim 10, wherein a lateral width of the first oxide diffusion region is substantially the same as a lateral width of the second oxide diffusion region from the top view.

13. The semiconductor structure of claim 10, wherein the padding region comprises a first dummy oxide diffusion region, wherein an upper edge of the first dummy oxide diffusion region is aligned with an upper edge of the first oxide diffusion region from the top view.

14. The semiconductor structure of claim 13, wherein a lateral width of the first dummy oxide diffusion region is substantially the same as a lateral width of the second oxide diffusion region from the top view.

15. The semiconductor structure of claim 10, wherein the padding region comprises a third dummy gate structure, wherein a third distance between the dummy gate structure and the third dummy gate structure is different from a fourth distance between the third dummy gate structure and the second dummy gate structure from the top view.

16. The semiconductor structure of claim 10, further comprising:
a first plurality of conductive lines disposed above the first region and parallel to the first isolation structure from the top view; and
a second plurality of conductive lines disposed above the second region and parallel to the first isolation structure, wherein a first number of the first plurality of conductive lines is different from a second number of the second plurality of conductive lines.

17. A semiconductor structure comprising:
a first region comprising:
a first cell comprising a first isolation structure and a second isolation structure;
a second cell comprising the second isolation structure and a third isolation structure; and
a third cell comprising the third isolation structure and a fourth isolation structure;
a second region comprising:
a fourth cell comprising a fifth isolation structure and a sixth isolation structure; and
a fifth cell comprising the sixth isolation structure and a seventh isolation structure; and
a padding region adjacent to the first region and the second region and disposed between the first region and the second region from the top view.

18. The semiconductor structure of claim 17, wherein an upper edge of the first isolation structure is aligned with an upper edge of the fifth isolation structure, and wherein a cell height of the first region is different from a cell height of the second region.

19. The semiconductor structure of claim 17, wherein the first cell comprises a first gate structure and a second gate structure, and the fourth cell comprises a third gate structure and a fourth gate structure, wherein a distance between the first gate structure and the second gate structure are substantially the same as a distance between the third gate structure and the fourth gate structure.

20. The semiconductor structure of claim 19, wherein the padding region is disposed between the first gate structure of the first region and the third gate structure of the second region from the top view.
